(19) United States
(12) Patent Application Publication
(10) Pub. No.: US 2026/0156872 A1
(43) Pub. Date: Jun. 4, 2026

(54) SEMICONDUCTOR DEVICE INCLUDING OXIDE SEMICONDUCTOR CHANNEL TRANSISTOR

(71) Applicant: Samsung Electronics Co., Ltd., Suwon-si (KR)

(72) Inventors: Changwook JEONG, Ulsan (KR); Miryeon KIM, Suwon-si (KR); Daewon HA, Suwon-si (KR); Min Hee CHO, Suwon-si (KR); Wonsok LEE, Suwon-si (KR); Minji HONG, Suwon-si (KR); Beomjin PARK, Ulsan (KR); Seokyeon SHIN, Ulsan (KR); Taehyun KIM, Ulsan (KR); Hyeongjun JANG, Ulsan (KR)

(73) Assignees: Samsung Electronics Co., Ltd., Suwon-si (KR); UNIST (ULSAN NATIONAL INSTITUTE OF SCIENCE AND TECHNOLOGY), Ulsan (KR)

(21) Appl. No.: 19/389,323

(22) Filed: Nov. 14, 2025

Related U.S. Application Data
(60) Provisional application No. 63/726,373, filed on Nov. 29, 2024.

(30) Foreign Application Priority Data
Aug. 14, 2025 (KR) 10-2025-0112973

(51) Int. Cl. H10D 30/67

(52) U.S. Cl. CPC H10D 30/6756; H10D 30/6713; H10D 30/6728; H10D 30/6757

(57) ABSTRACT

A semiconductor device includes an oxide semiconductor layer on a substrate, the oxide semiconductor layer including a channel region and contact regions spaced apart from each other in a first direction with the channel region therebetween, a gate electrode on the channel region of the oxide semiconductor layer, and electrodes respectively on the contact regions of the oxide semiconductor layer. A thickness of the oxide semiconductor layer in a second direction perpendicular to the first direction is greater than 0 nm and equal to or less than 10 nm. An energy band gap of each of the contact regions of the oxide semiconductor layer is less than an energy band gap of the channel region of the oxide semiconductor layer.

### CROSS-REFERENCE TO RELATED APPLICATIONS

This U.S. non-provisional patent application claims priority under 35 U.S.C. § 119 to Korean Patent Application No. 10-2025-0112973 filed on Aug. 14, 2025, and U.S. provisional Application No. 63/726,373 filed on Nov. 29, 2024, the entire contents of both of these application are hereby incorporated by reference.

### BACKGROUND

Some example embodiments of the present disclosure relate to a semiconductor memory device including an oxide semiconductor channel transistor and a method for manufacturing the same.

Semiconductor devices include an integrated circuit configured with metal oxide semiconductor field-effect transistors (MOSFETs). As the size and design rule of semiconductor devices are reduced, sizes of MOSFETs are increasingly being scaled down at a relatively faster rate. The scaling down of MOSFETs may cause deterioration of operational characteristics of semiconductor devices. Research is being carried out to develop different methods for manufacturing semiconductor devices having improved performance and having higher integration.

### SUMMARY

Some example embodiments of the present disclosure provide a semiconductor device including an oxide semiconductor channel transistor which facilitates relatively higher integration and has improved electrical characteristics and operational characteristics, and a method for manufacturing the same.

According to some example embodiments of the inventive concepts, a semiconductor device includes an oxide semiconductor layer on a substrate, the oxide semiconductor layer including a channel region and contact regions spaced apart from each other in a first direction with the channel region therebetween; a gate electrode on the channel region of the oxide semiconductor layer; and electrodes respectively on the contact regions of the oxide semiconductor layer. According to some example embodiments, a thickness of the oxide semiconductor layer in a second direction perpendicular to the first direction may be equal to or less than 10 nm. According to some example embodiments, an energy band gap of each of the contact regions of the oxide semiconductor layer may be less than an energy band gap of the channel region of the oxide semiconductor layer.

According to some example embodiments of the inventive concepts, a semiconductor device includes an oxide semiconductor layer on a substrate, the oxide semiconductor layer including a channel region and contact regions spaced apart from each other in a first direction with the channel region therebetween; a gate electrode on the channel region of the oxide semiconductor layer; and electrodes respectively on the contact regions of the oxide semiconductor layer. According to some example embodiments, the oxide semiconductor layer may include an amorphous oxide semiconductor, and an energy band gap of each of the contact regions of the oxide semiconductor layer may be less than an energy band gap of the channel region of the oxide semiconductor layer.

According to some example embodiments of the inventive concepts, a semiconductor device includes an oxide semiconductor layer on a substrate, the oxide semiconductor layer including a channel region and contact regions spaced apart from each other in a first direction with the channel region therebetween; a gate electrode on the channel region of the oxide semiconductor layer; and electrodes respectively on the contact regions of the oxide semiconductor layer. According to some example embodiments, the oxide semiconductor layer is configured such that a charge neutrality level (CNL) of the oxide semiconductor layer may be higher than a conduction band minimum (CBM) of the contact regions of the oxide semiconductor layer and lower than a conduction band minimum (CBM) of the channel region of the oxide semiconductor layer.

### BRIEF DESCRIPTION OF THE FIGURES

The accompanying drawings are included to provide a further understanding of the inventive concepts, and are incorporated in and constitute a part of this specification. The drawings illustrate embodiments of the inventive concepts and, together with the description, serve to explain principles of the inventive concepts. In the drawings:

FIG. 1 is a cross-sectional view of a semiconductor device according to some example embodiments of the inventive concepts.

FIG. 2 is a graph schematically illustrating a change in an energy band gap according to a thickness of an oxide semiconductor layer.

FIG. 3 is a cross-sectional view of a semiconductor device according to some example embodiments of the inventive concepts.

FIG. 4 is a cross-sectional view of a semiconductor device according to some example embodiments of the inventive concepts.

FIG. 5 is a graph schematically illustrating a change in an energy band gap according to an indium content in an oxide semiconductor layer.

FIG. 6 is a cross-sectional view illustrating a method for manufacturing a semiconductor device according to some example embodiments of the inventive concepts.

FIG. 7 is a cross-sectional view of a semiconductor device according to some example embodiments of the inventive concepts.

FIG. 8 is a cross-sectional view illustrating a method for manufacturing a semiconductor device according to some example embodiments of the inventive concepts.

FIG. 9 is a graph schematically illustrating a change in an energy band gap according to crystallinity of an oxide semiconductor layer.

FIG. 10 is a cross-sectional view of a semiconductor device according to some example embodiments of the inventive concepts.

FIGS. 11 and 12 are cross-sectional views illustrating a method for manufacturing a semiconductor device according to some example embodiments of the inventive concepts.

FIG. 13 is a cross-sectional view of a semiconductor device according to some example embodiments of the inventive concepts.

FIG. 14 is a cross-sectional view illustrating a method for manufacturing a semiconductor device according to some example embodiments of the inventive concepts.

FIG. 15 is a cross-sectional view of a semiconductor device according to some example embodiments of the inventive concepts.

FIG. 16 is a perspective view schematically illustrating a semiconductor device according to some example embodiments of the inventive concepts.

FIG. 17 is a cross-sectional view taken along line A-A′ of FIG. 16.

FIG. 18 is a perspective view schematically illustrating a semiconductor device according to some example embodiments of the inventive concepts.

FIG. 19 is a cross-sectional view taken along line A-A′ of FIG. 18.

FIG. 20 is a perspective view schematically illustrating a semiconductor device according to some example embodiments of the inventive concepts.

FIG. 21 is a cross-sectional view taken along line A-A′ of FIG. 20.

FIG. 22 is a cross-sectional view of a semiconductor device, taken along line A-A′ of FIG. 16, according to some example embodiments of the inventive concepts.

### DETAILED DESCRIPTION

Hereinafter, some example embodiments of the inventive concepts will be described in detail with reference to the accompanying drawings.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

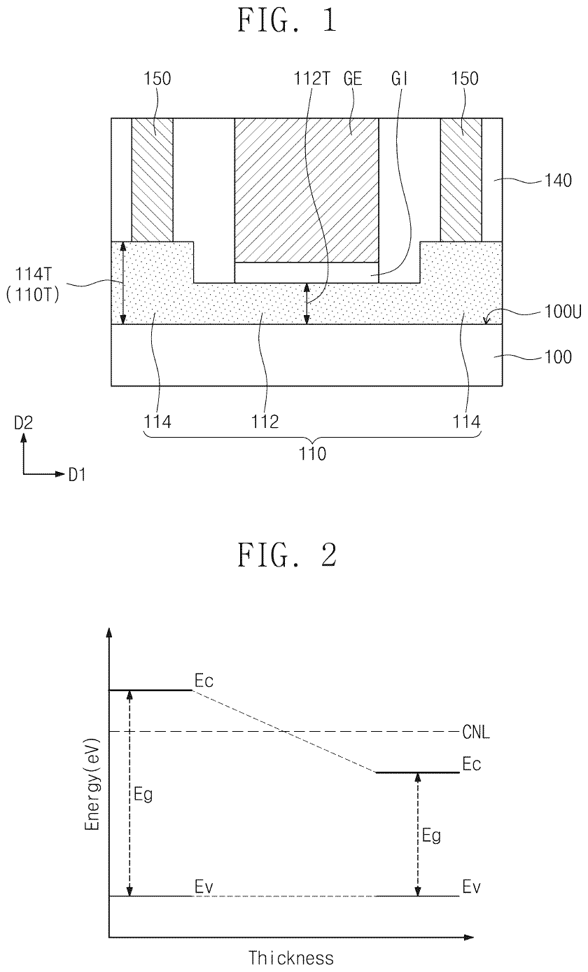

FIG. 1 is a cross-sectional view of a semiconductor device according to some example embodiments of the inventive concepts. FIG. 2 is a graph schematically illustrating a change in an energy band gap according to a thickness of an oxide semiconductor layer.

Referring to FIG. 1, an oxide semiconductor layer 110 may be disposed on a substrate 100. The substrate 100 may be a semiconductor substrate such as, for example, a silicon (Si) substrate, a germanium (Ge) substrate, a silicon-germanium (Si—Ge) substrate, or an SOI substrate.

The oxide semiconductor layer 110 may include a channel region 112 and contact regions 114. The channel region 112 may be interposed between the contact regions 114. The contact regions 114 may be spaced apart from each other in a first direction D1 with the channel region 112 therebetween, wherein the first direction D1 may be parallel to an upper surface 100U of the substrate 100.

The oxide semiconductor layer 110 may include, for example, InₓGa_{y}Zn_{z}O, InₓGa_{y}Si_{z}O, InₓSn_{y}Zn_{z}O, InₓZn_{y}O, InₓO, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. For example, the oxide semiconductor layer 110 may include an indium gallium zinc oxide (IGZO). According to some example embodiments, the oxide semiconductor layer 110 may include an amorphous oxide semiconductor (e.g., amorphous IGZO).

The oxide semiconductor layer 110 may have a thickness in a second direction D2 perpendicular to the first direction D1, wherein the second direction D2 may be perpendicular to the upper surface 100U of the substrate 100. A thickness 110T of the oxide semiconductor layer 110 may be greater than 0 nm and equal to or less than 10 nm (or about 10 nm), for example, equal to or less than 3 nm (or about 3 nm). According to some example embodiments, a thickness 114T of each of the contact regions 114 of the oxide semiconductor layer 110 may be greater than a thickness 112 T of the channel region 112 of the oxide semiconductor layer 110. In some example embodiments, the thickness 114T of each of the contact regions 114 may be equal to or less than 10 nm (or about 10 nm), for example, equal to or less than 3 nm (or about 3 nm).

A gate electrode GE and contact electrodes 150 may be disposed on the oxide semiconductor layer 120. The contact electrodes 150 may be disposed at both sides of the gate electrode GE and spaced apart from each other in the first direction D1 with the gate electrode GE therebetween. The gate electrode GE may be disposed between the contact electrodes 150. The gate electrode GE may be disposed on the channel region 112 of the oxide semiconductor layer 110, and the contact electrodes 150 may be respectively disposed on the contact regions 114 of the oxide semiconductor layer 110. A gate insulating pattern GI may be interposed between the oxide semiconductor layer 110 and the gate electrode GE. The gate insulating pattern GI may be interposed between the channel region 112 of the oxide semiconductor layer 110 and the gate electrode GE.

The gate electrode GE may include doped polysilicon, metal, conductive metal nitride, conductive metal silicide, conductive metal oxide, or a combination thereof. The gate electrode GE may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. According to some example embodiments, the gate electrode GE may include a two-dimensional semiconductor material, which may include, for example, graphene, carbon nanotube, or a combination thereof. The contact electrodes 150 may include doped polysilicon, metal, conductive metal nitride, conductive metal silicide, conductive metal oxide, or a combination thereof. The contact electrodes 150 may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. According to some example embodiments, the contact electrodes 150 may include a two-dimensional semiconductor material, which may include, for example, graphene, carbon nanotube, or a combination thereof. The gate insulating pattern GI may include a silicon oxide, a silicon oxynitride, a high dielectric layer having a higher dielectric constant than silicon oxide, or a combination thereof. The high dielectric layer may include a metal oxide or metal oxynitride. The high dielectric layer may include HfO₂, HfSiO, HfSiON, HfTaO, HfTiO, HfZrO, ZrO₂, Al₂O₃, or a combination thereof.

An interlayer insulating layer 140 may be disposed on the oxide semiconductor layer 110 and may cover the gate electrode GE and the contact electrodes 150. In some example embodiments, the interlayer insulating layer 140 may contact (or cover) the side surfaces of the sidewalls or the gate electrode GE and the contact electrodes 150. The interlayer insulating layer 140 may include, for example, silicon oxide, silicon nitride, and/or silicon oxynitride.

The oxide semiconductor layer 110, the gate electrode GE, and the contact electrodes 150 may constitute an oxide semiconductor channel transistor. The channel region 112 of the oxide semiconductor layer 110 may function as a channel of the transistor. The contact regions 114 of the oxide semiconductor layer 110 may be electrically connected to the contact electrodes 150, respectively.

Referring to FIGS. 1 and 2, when the oxide semiconductor layer 110 has a relatively thin thickness 110T of 10 nm (or about 10 nm) or less, an energy band gap Eg of the oxide semiconductor layer 110 may change according to the thickness 110T of the oxide semiconductor layer 110 due to a quantum confinement effect. The energy band gap Eg of the oxide semiconductor layer 110 may increase as the thickness 110T of the oxide semiconductor layer 110 decreases, and the energy band gap Eg of the oxide semiconductor layer 110 may decrease as the thickness 110T of the oxide semiconductor layer 110 increases. According to some example embodiments, the thickness 114T of each of the contact regions 114 of the oxide semiconductor layer 110 may be greater than the thickness 112T of the channel region 112 of the oxide semiconductor layer 110, and thus the energy band gap Eg of each of the contact regions 114 may be less than the energy band gap Eg of the channel region 112. In some example embodiments, a charge neutrality level (CNL) of the oxide semiconductor layer 110 may be higher than a conduction band minimum (CBM) Ec of each of the contact regions 114 and lower than a conduction band minimum (CBM) Ec of the channel region 112. The CNL may represent a Fermi level of a semiconductor surface for maintaining a charge neutrality state.

According to some example embodiments of the inventive concepts, the contact regions 114 of the oxide semiconductor layer 110 may have a smaller energy band gap Eg than that of the channel region 112 of the oxide semiconductor layer 110, and the CNL of the oxide semiconductor layer 110 may be higher than the CBM Ec of the contact regions 114. Accordingly, resistance of the contact regions 114, electrically connected to the contact electrodes 150, of the oxide semiconductor layer 110 may decrease. In addition, the channel region 112 of the oxide semiconductor layer 110 may have a larger energy band gap Eg than that of the contact regions 114, and the CNL of the oxide semiconductor layer 110 may be lower than the CBM Ec of the channel region 112. Accordingly, a threshold voltage Vth of the channel region 112 of the oxide semiconductor layer 110 may be greater than 0, and thus operational characteristics of the transistor may be improved. Furthermore, since the channel region 112 of the oxide semiconductor layer 110 has a larger energy band gap Eg than that of the contact regions 114, a leakage current of the transistor may be suppressed or limited or reduced. As a result, both electrical characteristics and operational characteristics of an oxide semiconductor channel transistor including the oxide semiconductor layer 110 having a thickness of 10 nm (or about 10 nm) or less may be improved.

Therefore, a semiconductor device including an oxide semiconductor channel transistor which has relatively higher integration and has improved electrical characteristics and operational characteristics may be obtained. Some example embodiments are also directed to a method for manufacturing such a semiconductor device having improved electrical characteristics and operational characteristics.

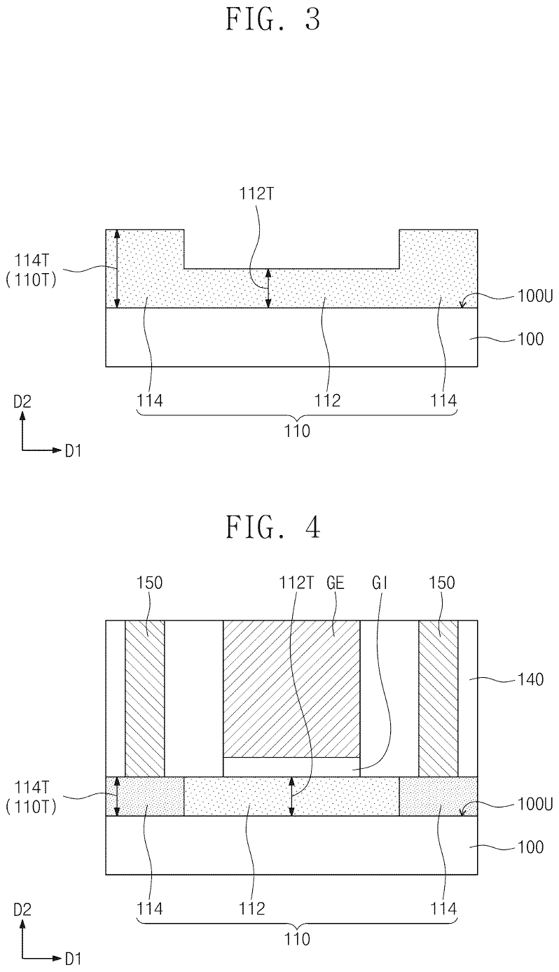

FIG. 3 is a cross-sectional view of a semiconductor device according to some example embodiments of the inventive concepts. The semiconductor device and the method in FIG. 3 may be best understood with reference to FIGS. 1 and 2 and the description will not be repeated for the sake of brevity.

Referring to FIG. 3, the oxide semiconductor layer 110 may be formed on the substrate 100. The oxide semiconductor layer 110 may be formed using, for example, at least one of physical vapor deposition (PVD), thermal chemical vapor deposition (CVD), low pressure-CVD (LP-CVD), plasma-enhanced CVD (PE-CVD), or atomic layer deposition (ALD). The oxide semiconductor layer 110 may have the thickness 110T in the second direction D2. The thickness 110T of the oxide semiconductor layer 110 may be more than 0 nm and equal to or less than 10 nm (or about 10 nm), for example, equal to or less than 3 nm (or about 3 nm).

The oxide semiconductor layer 110 may include the channel region 112 and the contact regions 114. The channel region 112 may be interposed between the contact regions 114. According to some example embodiments, an upper portion of the channel region 112 of the oxide semiconductor layer 110 may be recessed. The upper portion of the channel region 112 may be recessed using a dry etching or wet etching process, for example. Since the upper portion of the channel region 112 is recessed, the thickness 112T of the channel region 112 in the second direction D2 may be less than the thickness 114T of the contact regions 114 in the second direction D2.

Referring back to FIG. 1, the gate insulating pattern GI and the gate electrode GE may be formed on the channel region 112 of the oxide semiconductor layer 120. Forming the gate insulating pattern GI and the gate electrode GE may include, for example, sequentially forming a gate insulating layer and a gate electrode layer on the oxide semiconductor layer 120 and patterning the gate electrode layer and the gate insulating layer.

The interlayer insulating layer 140 may be formed on the oxide semiconductor layer 120 and may cover the gate insulating pattern GI and the gate electrode GE. In some example embodiments, the interlayer insulating layer 140 may contact (or cover) the side surfaces or the sidewalls of the gate electrode GE and the contact electrodes 150. The contact electrodes 150 may be formed in the interlayer insulating layer 140. Forming the contact electrodes 150 may include, for example, forming electrode holes that penetrate the interlayer insulating layer 140 and respectively expose the contact regions 114 of the oxide semiconductor layer 120 and forming a conductive layer filling the electrode holes.

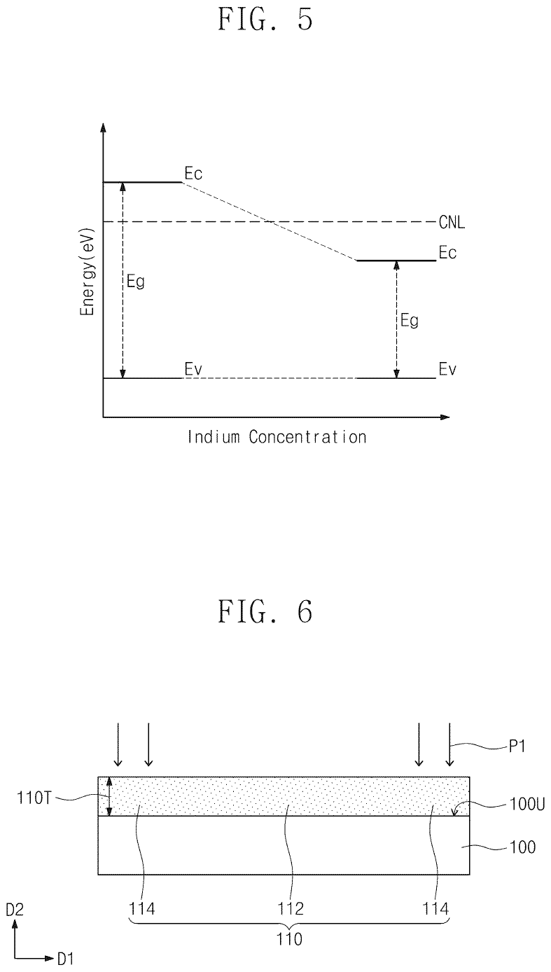

FIG. 4 is a cross-sectional view of a semiconductor device according to some example embodiments of the inventive concepts. FIG. 5 is a graph schematically illustrating a change in an energy band gap according to an indium content in an oxide semiconductor layer. The semiconductor device in FIG. 4 may be same as or similar in some respects to the semiconductor device of FIGS. 1 and 2, and therefore may be best understood with reference thereto where like numerals indicate like elements not described again in detail.

Referring to FIG. 4, the thickness 110T of the oxide semiconductor layer 110 may be greater than 0 nm and equal to or less than 10 nm (or about 10 nm), for example, equal to or less than 3 nm (or about 3 nm). According to some example embodiments, the thickness 114T of each of the contact regions 114 of the oxide semiconductor layer 110 may be substantially the same as the thickness 112T of the channel region 112 of the oxide semiconductor layer 110. The oxide semiconductor layer 110 may include a first metal, and a content (or concentration) of the first metal in each of the contact regions 114 of the oxide semiconductor layer 110 may be higher than a content of the first metal in the channel region 112 of the oxide semiconductor layer 110. For example, the first metal may be indium (In), and an indium content in each of the contact regions 114 of the oxide semiconductor layer 110 may be higher than an indium content in the channel region 112 of the oxide semiconductor layer 110.

Referring to FIGS. 4 and 5, the energy band gap Eg of the oxide semiconductor layer 110 may change according to the indium content (or concentration) in the oxide semiconductor layer 110. When the indium content (or concentration) in the oxide semiconductor layer 110 increases, a content (or concentration) of indium oxide having a relatively small band gap may increase, and thus the energy band gap Eg of the oxide semiconductor layer 110 may decrease. When the indium content (or concentration) in the oxide semiconductor layer 110 decreases, a content (or concentration) of indium oxide having a relatively small band gap may decrease, and thus the energy band gap Eg of the oxide semiconductor layer 110 may increase. According to some example embodiments, the indium content (or concentration) in each of the contact regions 114 of the oxide semiconductor layer 110 may be higher than the indium content (or concentration) in the channel region 112 of the oxide semiconductor layer 110, and thus the energy band gap Eg of each of the contact regions 114 may be less than the energy band gap Eg of the channel region 112. In this case, the charge neutrality level (CNL) of the oxide semiconductor layer 110 may be higher than the CBM Ec of each of the contact regions 114 and lower than the conduction band minimum (CBM) Ec of the channel region 112.

According to some example embodiments of the inventive concepts, the resistance of the contact regions 114 of the oxide semiconductor layer 110 may reduce, and the threshold voltage Vth of the channel region 112 of the oxide semiconductor layer 110 may be more than 0. Furthermore, since the channel region 112 of the oxide semiconductor layer 110 has a larger energy band gap Eg than that of the contact regions 114, a leakage current of the transistor may be suppressed or reduced or limited.

Therefore, both the electrical characteristics and operational characteristics of an oxide semiconductor channel transistor including the oxide semiconductor layer 110 having a thickness of 10 nm (or about 10 nm) or less may be improved.

FIG. 6 is a cross-sectional view illustrating a method for manufacturing a semiconductor device according to some example embodiments of the inventive concepts. The semiconductor device and the method in FIG. 6 may be best understood with reference to FIGS. 1 and 3 and the description will not be repeated for the sake of brevity.

Referring to FIG. 6, the oxide semiconductor layer 110 may be formed on the substrate 100. The thickness 110T of the oxide semiconductor layer 110 may be greater than 0 nm and equal to or less than 10 nm (or about 10 nm), for example, equal to or less than 3 nm (or about 3 nm). The oxide semiconductor layer 110 may include a first metal.

The oxide semiconductor layer 110 may include the channel region 112 and the contact regions 114. The channel region 112 may be interposed between the contact regions 114. According to some example embodiments, an ion injection process P1 for injecting the first metal into the contact regions 114 of the oxide semiconductor layer 110 may be performed. Accordingly, a content (or concentration) of the first metal in each of the contact regions 114 of the oxide semiconductor layer 110 may be higher than a content of the first metal in the channel region 112 of the oxide semiconductor layer 110. For example, the first metal may be indium (In), and an indium content in each of the contact regions 114 of the oxide semiconductor layer 110 may be higher than an indium content in the channel region 112 of the oxide semiconductor layer 110.

A subsequent process is substantially the same as (or similar in some respects to) the method for manufacturing a semiconductor device described with reference to FIGS. 1 and 3.

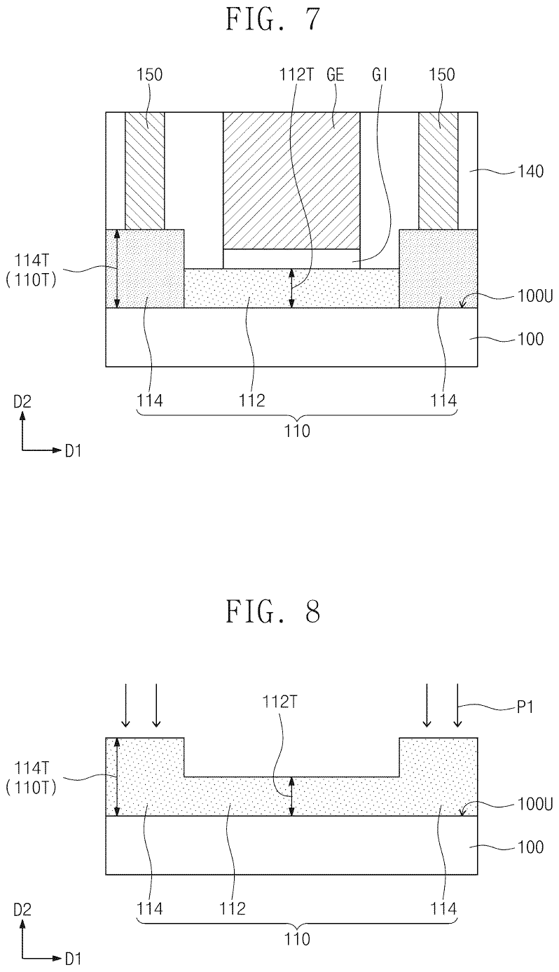

FIG. 7 is a cross-sectional view of a semiconductor device according to some example embodiments of the inventive concepts. The semiconductor device of FIG. 7 may be same as or similar in some respects to the semiconductor devices of FIGS. 1, 2, 4, and 5, and therefore may be best understood with reference thereto where like numerals indicate like elements not described again in detail.

Referring to FIG. 7, the thickness 110T of the oxide semiconductor layer 110 may be greater than 0 nm and equal to or less than 10 nm (or about 10 nm), for example, equal to or less than 3 nm (or about 3 nm). According to some example embodiments, the thickness 114T of each of the contact regions 114 of the oxide semiconductor layer 110 may be more than the thickness 112T of the channel region 112 of the oxide semiconductor layer 110. In some example embodiments, the thickness 114T of each of the contact regions 114 may be equal to or less than 10 nm (or about 10 nm), for example, equal to or less than 3 nm (or about 3 nm). In addition, the oxide semiconductor layer 110 may include a first metal, and a content of the first metal in each of the contact regions 114 of the oxide semiconductor layer 110 may be higher than a content (or concentration) of the first metal in the channel region 112 of the oxide semiconductor layer 110. For example, the first metal may be indium (In), and an indium content in each of the contact regions 114 of the oxide semiconductor layer 110 may be higher than an indium content in the channel region 112 of the oxide semiconductor layer 110.

FIG. 8 is a cross-sectional view illustrating a method for manufacturing a semiconductor device according to some example embodiments of the inventive concepts. The semiconductor device and the method in FIG. 8 may be best understood with reference to FIGS. 1, 3, and 6 and the description will not be repeated for the sake of brevity.

Referring to FIG. 8, the oxide semiconductor layer 110 may be formed on the substrate 100. The thickness 110T of the oxide semiconductor layer 110 may be greater than 0 nm and equal to or less than 10 nm (or about 10 nm), for example, equal to or less than 3 nm (or about 3 nm).

The oxide semiconductor layer 110 may include the channel region 112 and the contact regions 114. The channel region 112 may be interposed between the contact regions 114. According to some example embodiments, an upper portion of the channel region 112 of the oxide semiconductor layer 110 may be recessed. Since the upper portion of the channel region 112 is recessed, the thickness 112T of the channel region 112 in the second direction D2 may be less than the thickness 114T of the contact regions 114 in the second direction D2.

The oxide semiconductor layer 110 may include a first metal. An ion injection process P1 for injecting the first metal into the contact regions 114 of the oxide semiconductor layer 110 may be performed. Accordingly, a content (or concentration) of the first metal in each of the contact regions 114 of the oxide semiconductor layer 110 may be higher than a content of the first metal in the channel region 112 of the oxide semiconductor layer 110. For example, the first metal may be indium (In), and an indium content in each of the contact regions 114 of the oxide semiconductor layer 110 may be higher than an indium content in the channel region 112 of the oxide semiconductor layer 110.

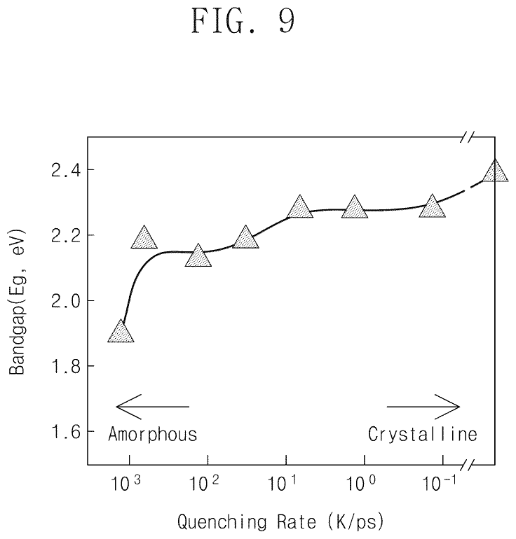

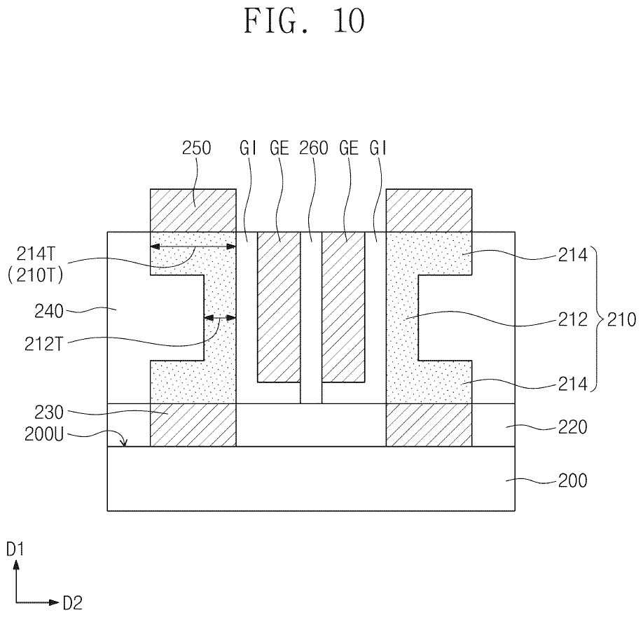

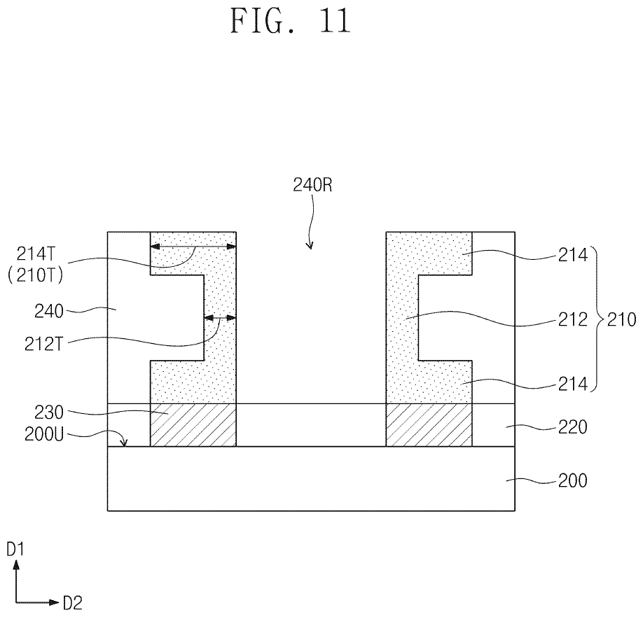

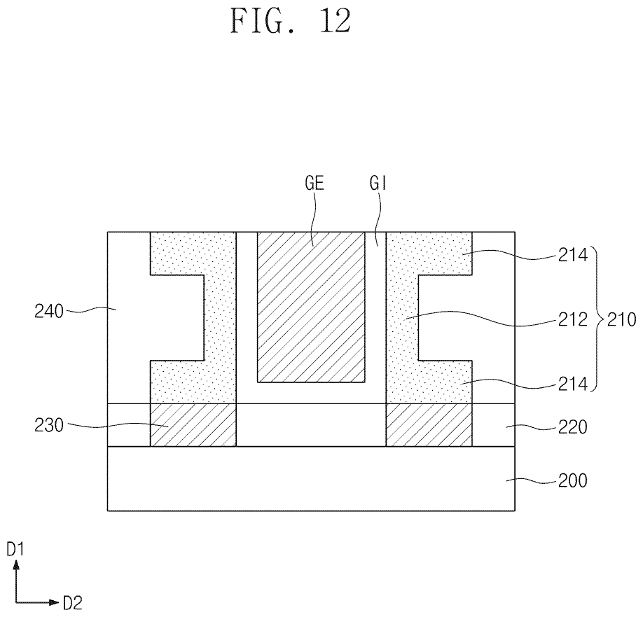

FIG. 9 is a graph schematically illustrating a change in an energy band gap according to crystallinity of an oxide semiconductor layer.

Referring to FIG. 9, the energy band gap Eg of the oxide semiconductor layer 110 may change according to crystallinity of the oxide semiconductor layer 110. When the crystallinity of the oxide semiconductor layer 110 is low (e.g., when the oxide semiconductor layer 110 is amorphous), the energy band gap Eg of the oxide semiconductor layer 110 may decrease. When the crystallinity of the oxide semiconductor layer 110 is high (e.g., when the oxide semiconductor layer 110 is crystalline), the energy band gap Eg of the oxide semiconductor layer 110 may increase. According to some example embodiments, the contact regions 114 of the oxide semiconductor layer 110 described with reference to FIGS. 1, 4, and 7 may have lower crystallinity than that of the channel region 112 of the oxide semiconductor layer 110. Accordingly, the energy band gap Eg of each of the contact regions 114 may be less than the energy band gap Eg of the channel region 112.

According to some example embodiments, the energy band gap Eg of the oxide semiconductor layer 110 may change according to a density of an oxide semiconductor in the oxide semiconductor layer 110. When the density of an oxide semiconductor in the oxide semiconductor layer 110 is low (e.g., when the oxide semiconductor layer 110 is amorphous), the energy band gap Eg of the oxide semiconductor layer 110 may decrease. When the density of an oxide semiconductor in the oxide semiconductor layer 110 is high (e.g., when the oxide semiconductor layer 110 is crystalline), the energy band gap Eg of the oxide semiconductor layer 110 may increase. According to some example embodiments, the density of an oxide semiconductor in each of the contact regions 114 of the oxide semiconductor layer 110 described with reference to FIGS. 1, 4, and 7 may be lower than the density of an oxide semiconductor in the channel region 112 of the oxide semiconductor layer 110. Accordingly, the energy band gap Eg of each of the contact regions 114 may be less than the energy band gap Eg of the channel region 112.

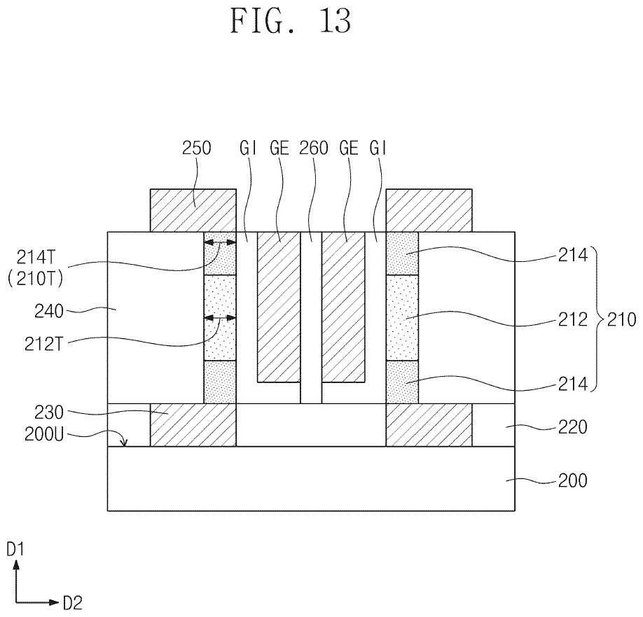

FIG. 10 is a cross-sectional view of a semiconductor device according to some example embodiments of the inventive concepts.

Referring to FIG. 10, a lower insulating layer 220 may be disposed on a substrate 200. The substrate 200 may be a semiconductor substrate such as, for example, a silicon (Si) substrate, a germanium (Ge) substrate, a silicon-germanium (Si-Ge) substrate, or an SOI substrate. The lower insulating layer 220 may include, for example, silicon oxide, silicon nitride, and/or silicon oxynitride.

Lower electrodes 230 may be disposed in the lower insulating layer 220. The lower electrodes 230 may each penetrate the lower insulating layer 220 in the first direction D1 perpendicular to an upper surface 200U of the substrate 200. The lower electrodes 230 may be spaced apart from each other in the second direction D2 parallel to the upper surface 200U of the substrate 200. The lower electrodes 230 may include doped polysilicon, metal, conductive metal nitride, conductive metal silicide, conductive metal oxide, or a combination thereof. The lower electrodes 230 may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. The lower electrodes 230 may include a two-dimensional semiconductor material, which may include, for example, graphene, carbon nanotube, or a combination thereof.

Oxide semiconductor layers 210 may be disposed on the lower electrodes 230, respectively. The oxide semiconductor layers 210 may extend in the first direction D1 and may be spaced apart from each other in the second direction D2. The oxide semiconductor layers 210 may each include a channel region 212 and contact regions 214. The channel region 212 may be interposed between the contact regions 214. The contact regions 214 may be spaced apart from each other in the first direction D1 with the channel region 212 therebetween.

The oxide semiconductor layers 210 may include, for example, InₓGa_{y}Zn_{z}O, InₓGa_{y}Si_{z}O, InₓSn_{y}Zn_{z}O, InₓZn_{y}O, InₓO, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. For example, the oxide semiconductor layers 210 may include an indium gallium zinc oxide (IGZO). According to some example embodiments, the oxide semiconductor layers 210 may include an amorphous oxide semiconductor (e.g., amorphous IGZO).

The oxide semiconductor layers 210 may each have a thickness in the second direction D2. The thickness 210T of each of the oxide semiconductor layers 210 may be greater than 0 nm and equal to or less than 10 nm (or about 10 nm), for example, equal to or less than 3 nm (or about 3 nm). According to some example embodiments, the thickness 214T of each of the contact regions 214 of each of the oxide semiconductor layers 210 may be greater than the thickness 212T of the channel region 212 of each of the oxide semiconductor layers 210. In some example embodiments, the thickness 214T of each of the contact regions 214 may be equal to or less than 10 nm (or about 10 nm), for example, equal to or less than 3 nm (or about 3 nm).

Gate electrodes GE and gate insulating patterns GI may be disposed between the oxide semiconductor layers 210. The gate electrodes GE may be spaced apart from each other in the second direction D2 between the oxide semiconductor layers 210 and may extend in the first direction D1. The gate insulating patterns GI may each be interposed between each of the gate electrodes GE and each of the oxide semiconductor layers 210 and may extend between each of the gate electrodes GE and the lower insulating layer 220.

The gate electrodes GE may include doped polysilicon, metal, conductive metal nitride, conductive metal silicide, conductive metal oxide, or a combination thereof. The gate electrodes GE may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. According to some example embodiments, the gate electrodes GE may include a two-dimensional semiconductor material, which may include, for example, graphene, carbon nanotube, or a combination thereof. The gate insulating patterns GI may include a silicon oxide, a silicon oxynitride, a high dielectric layer having a higher dielectric constant than silicon oxide, or a combination thereof. The high dielectric layer may include a metal oxide or metal oxynitride. The high dielectric layer may include HfO₂, HfSiO, HfSiON, HfTaO, HfTiO, HfZrO, ZrO₂, Al₂O₃, or a combination thereof.

An isolation insulating pattern 260 may be interposed between the gate electrodes GE and may extend in the first direction D1. The isolation insulating pattern 260 may extend in the first direction D1 between the gate insulating patterns GI. The gate electrodes GE may be spaced apart from each other in the second direction D2 and electrically separated from each other by the isolation insulating pattern 260. The gate insulating patterns GI may be spaced apart from each other in the second direction D2 with the isolation insulating pattern 260 and the gate electrodes GE therebetween. The isolation insulating pattern 260 may include, for example, silicon oxide, silicon nitride, and/or silicon oxynitride.

A mold layer 240 may be disposed on the lower insulating layer 220. The oxide semiconductor layers 210, the gate insulating patterns GI, the gate electrodes GE, and the isolation insulating pattern 260 may be disposed in the mold layer 240 and the mold layer 240 may laterally contact (e.g., in the second direction D2) the oxide semiconductor layers 210, the gate insulating patterns GI, the gate electrodes GE, and the isolation insulating pattern 260. The mold layer 240 may include, for example, silicon oxide, silicon nitride, and/or silicon oxynitride.

Upper electrodes 250 may be respectively disposed on the oxide semiconductor layers 210 and spaced apart from each other in the second direction D2. The upper electrodes 250 may include doped polysilicon, metal, conductive metal nitride, conductive metal silicide, conductive metal oxide, or a combination thereof. The upper electrodes 250 may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. The upper electrodes 250 may include a two-dimensional semiconductor material, which may include, for example, graphene, carbon nanotube, or a combination thereof.

Each gate electrode GE may be disposed on the channel region 212 of each oxide semiconductor layer 210. Each gate insulating pattern GI may be interposed between the channel region 212 of each oxide semiconductor layer 210 and each gate electrode GE. Each lower electrode 230 may be adjacent to one of the contact regions 214 of each oxide semiconductor layer 210 and may be electrically connected to the one of the contact regions 214. Each upper electrode 250 may be adjacent to another one of the contact regions 214 of each oxide semiconductor layer 210 and may be electrically connected to the other one of the contact regions 214.

Each oxide semiconductor layer 210, each gate electrode GE, each lower electrode 230, and each upper electrode 250 may constitute an oxide semiconductor channel transistor. The channel region 212 of each oxide semiconductor layer 210 may function as a channel of the transistor. The contact regions 214 of each oxide semiconductor layer 210 may be electrically connected to one of the lower electrodes 230 and one of the upper electrodes 250, respectively.

The semiconductor device according to some example embodiments is substantially the same as (or similar in some respects to) the semiconductor device described with reference to FIGS. 1 and 2. In the semiconductor device of FIG. 10, each oxide semiconductor layer 210, each gate electrode GE, each lower electrode 230, and each upper electrode 250 constitute a vertical channel transistor.

FIGS. 11 and 12 are cross-sectional views illustrating a method for manufacturing a semiconductor device according to some example embodiments of the inventive concepts. The semiconductor device and method of FIGS. 11 and 12 may be same as or similar in some respects to the semiconductor device of FIG. 10, and therefore may be best understood with reference thereto where like numerals indicate like elements not described again in detail.

Referring to FIG. 11, the lower insulating layer 220 and the lower electrodes 230 may be disposed on the substrate 200. Forming the lower insulating layer 220 and the lower electrodes 230 may include, for example, forming lower electrode holes spaced apart from each other in the second direction D2 in the lower insulating layer 220, forming a lower electrode layer filling the lower electrode holes on the lower insulating layer 220, and planarizing the lower electrode layer until an upper surface of the lower insulating layer 220 is exposed.

The mold layer 240 may be formed on the lower insulating layer 220. A recess region 240R may be formed so as to penetrate the mold layer 240 in the first direction D1. The recess region 240R may penetrate the mold layer 240 and expose an upper surface of the lower insulating layer 220 between the lower electrodes 230 and expose inner side surfaces of the mold layer 240. Inner side surfaces of a lower portion of the mold layer 240 and inner side surfaces of an upper portion of the mold layer 240 may be laterally (e.g., in a direction parallel to the upper surface 200U of the substrate 200) recessed. Since the inner side surfaces of the lower portion of the mold layer 240 are laterally recessed, the inner side surfaces of the mold layer 240 may have a protrusion and recess structure.

The oxide semiconductor layers 210 may be formed in the recess region 240R so as to cover the inner side surfaces of the mold layer 240, respectively. The oxide semiconductor layers 210 may respectively cover upper surfaces of the lower electrodes 230. Forming the oxide semiconductor layers 210 may include, for example, forming an oxide semiconductor layer that partially fills the recess region 240R and conformally covers the inner side surfaces of the mold layer 240, and forming the oxide semiconductor layers 210 spaced apart from each other in the second direction D2 in the recess region 240R by anisotropically etching the oxide semiconductor layer.

The oxide semiconductor layers 210 may each include a channel region 212 and contact regions 214. The channel region 212 may be interposed between the contact regions 214. The contact regions 214 may be spaced apart from each other in the first direction D1 with the channel region 212 therebetween. The oxide semiconductor layers 210 may be formed so as to cover the inner side surfaces (e.g., inner side surfaces having a protrusion and recess structure) of the mold layer 240, and thus the thickness 214T of each of the contact regions 214 of each of the oxide semiconductor layers 210 may be larger than the thickness 212T of the channel region 212 of each of the oxide semiconductor layers 210.

Referring to FIG. 12, the gate insulating pattern GI and the gate electrode GE may be formed so as to fill a remaining portion of the recess regions 240R. Forming the gate insulating pattern GI and the gate electrode GE may include, for example, forming a gate insulating layer filling a portion of the recess region 240R on the mold layer 240, forming a gate electrode layer filling a remaining portion of the recess region 240R on the gate insulating layer, and planarizing the gate insulating layer and the gate electrode layer until an upper surface of the mold layer 240 is exposed.

Referring back to FIG. 10, the isolation insulating pattern 260 may be formed so as to penetrate the gate insulating pattern GI and the gate electrode GE. Forming the isolation insulating pattern 260 may include, for example, forming an isolation hole penetrating the gate insulating pattern GI and the gate electrode GE in the first direction D1, forming an insulating layer filling the isolation hole, and planarizing the insulating layer until upper surfaces of the gate insulating pattern GI and the gate electrode GE are exposed. The gate electrode GE may be separated by the isolation insulating pattern 260 into a pair of gate electrodes GE spaced apart from each other in the second direction D2, and the gate insulating pattern GI may be separated by the isolation insulating pattern 260 into a pair of gate insulating patterns GI spaced apart from each other in the second direction D2. The upper electrodes 250 may be respectively formed on the oxide semiconductor layers 210.

FIG. 13 is a cross-sectional view of a semiconductor device according to some example embodiments of the inventive concepts. The semiconductor device of FIG. 13 may be same as or similar in some respects to the semiconductor device of FIG. 10, and therefore may be best understood with reference thereto where like numerals indicate like elements not described again in detail.

Referring to FIG. 13, the oxide semiconductor layers 210 may each have a thickness in the second direction D2. The thickness 210T of each of the oxide semiconductor layers 210 may be greater than 0 nm and equal to or less than 10 nm (or about 10 nm), for example, equal to or less than 3 nm (or about 3 nm). According to some example embodiments, the thickness 214T of each of the contact regions 214 of each oxide semiconductor layer 210 may be substantially the same as the thickness 212T of the channel region 212 of each oxide semiconductor layer 210. The oxide semiconductor layers 210 may include a first metal. A content (or concentration) of the first metal in each of the contact regions 214 of each oxide semiconductor layer 210 may be higher than a content of the first metal in the channel region 212 of each oxide semiconductor layer 210. For example, the first metal may be indium (In), and an indium content in each of the contact regions 214 of each oxide semiconductor layer 210 may be higher than an indium content in the channel region 212 of each oxide semiconductor layer 210.

The semiconductor device according to some example embodiments is substantially the same as (or similar in respects to) the semiconductor device described with reference to FIGS. 4 and 5. In the semiconductor device of FIG. 13, each oxide semiconductor layer 210, each gate electrode GE, each lower electrode 230, and each upper electrode 250 constitute a vertical channel transistor.

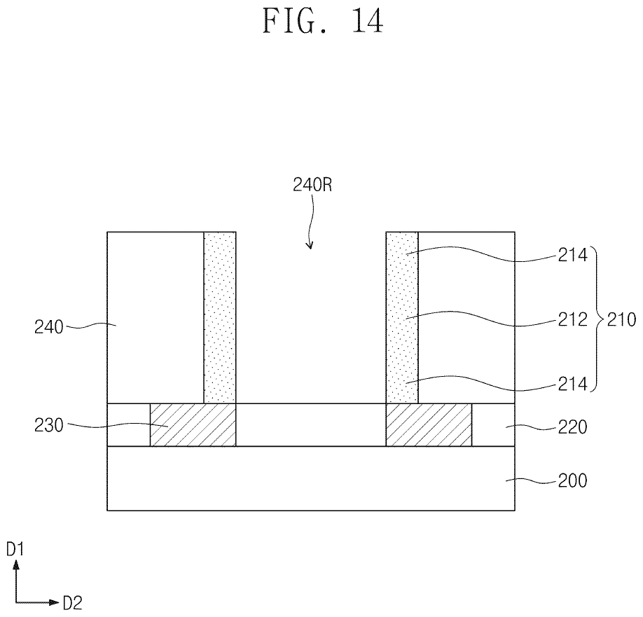

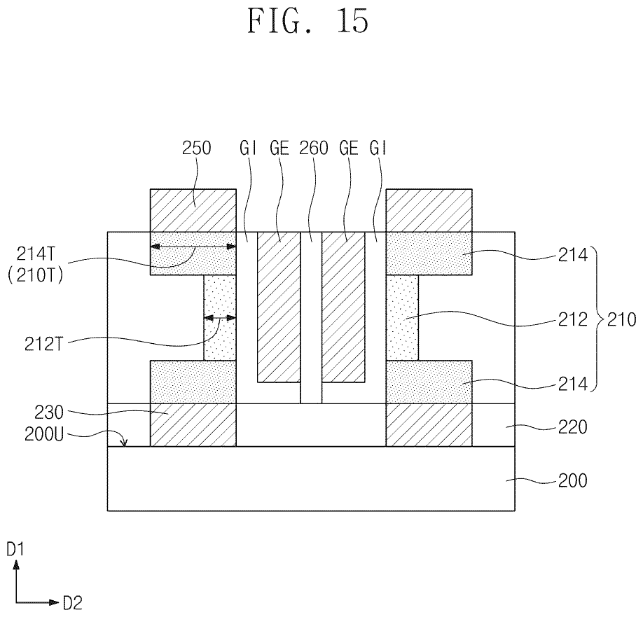

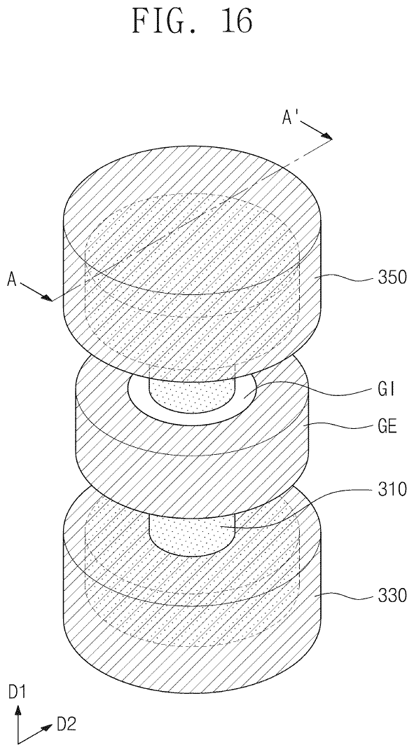

FIG. 14 is a cross-sectional view illustrating a method for manufacturing a semiconductor device according to some example embodiments of the inventive concepts. The semiconductor device and method of FIG. 14 may be same as or similar in some respects to the semiconductor device of FIGS. 10, 11, and 12, and therefore may be best understood with reference thereto where like numerals indicate like elements not described again in detail.

Referring to FIG. 14, the mold layer 240 may be formed on the lower insulating layer 220, and the recess region 240R may be formed so as to penetrate the mold layer 240 in the first direction D1. The recess region 240R may penetrate the mold layer 240 and expose an upper surface of the lower insulating layer 220 and inner side surfaces of the mold layer 240. According to some example embodiments, a process of laterally recessing the inner side surfaces of the upper portion and lower portion of the mold layer 240 may be omitted.

The oxide semiconductor layers 210 may be formed in the recess region 240R so as to cover the inner side surfaces of the mold layer 240, respectively. The oxide semiconductor layers 210 may each include a channel region 212 and contact regions 214. The channel region 212 may be interposed between the contact regions 214. The contact regions 214 may be spaced apart from each other in the first direction D1 with the channel region 212 therebetween. According to some example embodiments, the oxide semiconductor layers 210 may include a first metal. Forming the oxide semiconductor layers 210 may further include performing an ion injection process for injecting the first metal into lower portions and upper portions of the oxide semiconductor layers 210. Accordingly, a content (or concentration) of the first metal in each of the contact regions 214 of each oxide semiconductor layer 210 may be higher than a content of the first metal in the channel region 212 of each oxide semiconductor layer 210. For example, the first metal may be indium (In), and an indium content in each of the contact regions 214 of each oxide semiconductor layer 210 may be higher than an indium content in the channel region 212 of each oxide semiconductor layer 210.

A subsequent process is substantially the same as (or similar in some respects to) the method for manufacturing a semiconductor device described with reference to FIGS. 10 to 12.

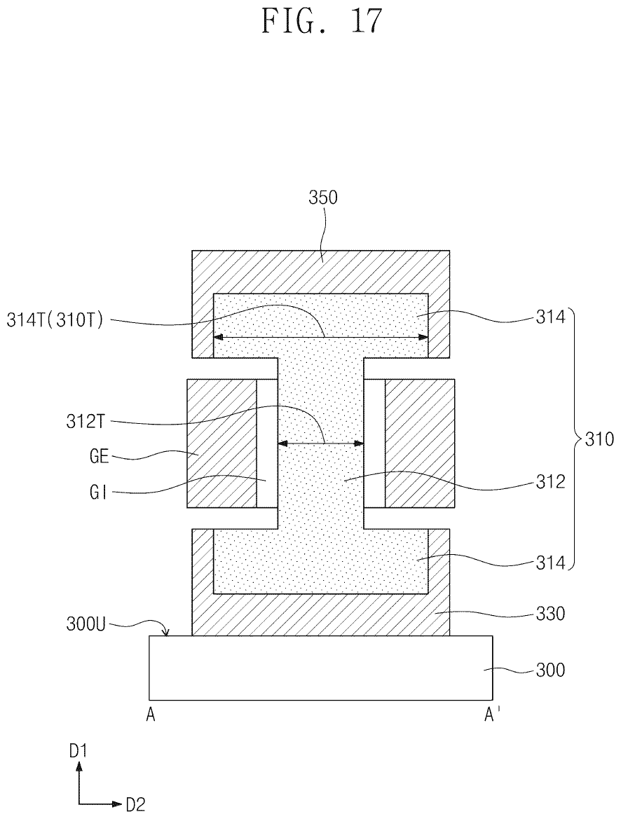

FIG. 15 is a cross-sectional view of a semiconductor device according to some example embodiments of the inventive concepts. The semiconductor device of FIG. 15 may be same as or similar in some respects to the semiconductor devices of FIGS. 10 and 13, and therefore may be best understood with reference thereto where like numerals indicate like elements not described again in detail.

Referring to FIG. 15, the oxide semiconductor layers 210 may each have a thickness in the second direction D2. The thickness 210T of each of the oxide semiconductor layers 210 may be greater than 0 nm and equal to or less than 10 nm (or about 10 nm), for example, equal to or less than 3 nm (or about 3 nm). According to some example embodiments, the thickness 214T of each of the contact regions 214 of each of the oxide semiconductor layers 210 may be greater than the thickness 212T of the channel region 212 of each of the oxide semiconductor layers 210. In some example embodiments, the thickness 214T of each of the contact regions 214 may be equal to or less than 10 nm (or about 10 nm), for example, equal to or less than 3 nm (or about 3 nm). The oxide semiconductor layers 210 may include a first metal. A content (or concentration) of the first metal in each of the contact regions 214 of each oxide semiconductor layer 210 may be higher than a content (or concentration) of the first metal in the channel region 212 of each oxide semiconductor layer 210. For example, the first metal may be indium (In), and an indium content in each of the contact regions 214 of each oxide semiconductor layer 210 may be higher than an indium content in the channel region 212 of each oxide semiconductor layer 210.

The semiconductor device according to some example embodiments is substantially the same as (or similar in some respects to) the semiconductor device described with reference to FIG. 7. In the semiconductor device of FIG. 15, each oxide semiconductor layer 210, each gate electrode GE, each lower electrode 230, and each upper electrode 250 constitute a vertical channel transistor. The semiconductor device according to some example embodiments may be formed using a method that is substantially the same as (or similar in some respects to) the method for manufacturing a semiconductor device described with reference to FIGS. 10, 11, 12, and 14.

FIG. 16 is a perspective view schematically illustrating a semiconductor device according to some example embodiments of the inventive concepts, and FIG. 17 is a cross-sectional view taken along line A-A′ of FIG. 16.

The semiconductor device of FIG. 16 may be a generally cylindrical structure. Referring to FIGS. 16 and 17, a lower electrode 330 may be disposed on a substrate 300. The substrate 300 and the lower electrode 330 are substantially the same as (or similar in some respects to) the substrate 200 and the lower electrodes 230 described with reference to FIG. 10.

An oxide semiconductor layer 310 may be disposed on the lower electrode 330. The oxide semiconductor layer 310 may extend in the first direction D1 perpendicular to an upper surface 300U of the substrate 300. The oxide semiconductor layer 310 may include a channel region 312 and contact regions 314. The channel region 312 may be interposed between the contact regions 314. The contact regions 314 may be spaced apart from each other in the first direction D1 with the channel region 312 therebetween.

The oxide semiconductor layer 310 may have a thickness in the second direction D2 parallel to the upper surface 300U of the substrate 300. A thickness 310T of the oxide semiconductor layer 310 may be greater than 0 nm and equal to or less than 10 nm (or about 10 nm), for example, equal to or less than 3 nm (or about 3 nm). According to some example embodiments, a thickness 314T of each of the contact regions 314 of the oxide semiconductor layer 310 may be greater than a thickness 312T of the channel region 312 of the oxide semiconductor layer 310. In some example embodiments, the thickness 314T of each of the contact regions 314 may be equal to or less than 10 nm (or about 10 nm), for example, equal to or less than 3 nm (or about 3 nm). The oxide semiconductor layer 310 is substantially the same as (or similar in some respects to) the oxide semiconductor layers 210 described with reference to FIG. 10.

A gate electrode GE may be disposed on the oxide semiconductor layer 310. According to some example embodiments, the gate electrode GE may surround a side surface of the oxide semiconductor layer 310. The gate electrode GE may surround (or may be wrapped around) a side surface of the channel region 312 of the oxide semiconductor layer 310. A gate insulating pattern GI may be interposed between the side surface of the oxide semiconductor layer 310 and the gate electrode GE. The gate insulating pattern GI may surround (or may be wrapped around) the side surface of the oxide semiconductor layer 310. One or more other aspects of the gate electrode GE and the gate insulating pattern GI are substantially the same as (or similar in some respects to) the gate electrodes GE and the gate insulating patterns GI described with reference to FIG. 10 and may be best understood with reference thereto.

An upper electrode 350 may be disposed on the oxide semiconductor layer 310. The upper electrode 350 is substantially the same as (or similar in some respects to) the upper electrode 250 described with reference to FIG. 10. According to some example embodiments, the lower electrode 330 may surround a lower surface and side surface of one of the contact regions 314 of the oxide semiconductor layer 310, and the upper electrode 350 may surround an upper surface and side surface of the other one of the contact regions 314 of the oxide semiconductor layer 310.

The oxide semiconductor layer 310, the gate electrode GE, the lower electrode 330, and the upper electrode 350 may constitute an oxide semiconductor channel transistor. The channel region 312 of the oxide semiconductor layer 310 may function as a channel of the transistor. The contact regions 314 of the oxide semiconductor layer 310 may be electrically connected to the lower electrode 330 and the upper electrode 350.

The semiconductor device according to some example embodiments is substantially the same as (or similar in some respects to) the semiconductor device described with reference to FIG. 10. In the semiconductor device of FIG. 16, the oxide semiconductor layer 310, the gate electrode GE, the lower electrode 330, and the upper electrode 350 constitute a gate-all-around type transistor.

The semiconductor device according to some example embodiments may be formed using the following methods, but example embodiments of the inventive concepts are not limited thereto.

Referring back to FIGS. 16 and 17, the lower electrode 330 may be formed on the substrate 300, and one of the contact regions 314 of the oxide semiconductor layer 310 may be formed on the lower electrode 330. According to some example embodiments, the lower electrode 330 may be formed so as to surround the lower surface and side surface of one of the contact regions 314 of the oxide semiconductor layer 310. A mold layer may be formed on the lower electrode 330 and the one of the contact regions 314 of the oxide semiconductor layer 310, and a channel hole may be formed in the mold layer. The channel hole may penetrate the mold layer in the first direction D1 and expose the one of the contact regions 314 of the oxide semiconductor layer 310. The channel region 312 of the oxide semiconductor layer 310 may be formed so as to fill the channel hole. A recess region exposing a side surface of the channel region 312 of the oxide semiconductor layer 310 may be formed in the mold layer, and the gate insulating pattern GI and the gate electrode GE may be formed in the recess region. The gate insulating pattern GI and the gate electrode GE may be formed so as to surround the side surface of the channel region 312 of the oxide semiconductor layer 310. Thereafter, the other one of the contact regions 314 of the oxide semiconductor layer 310 may be formed on the channel region 312 of the oxide semiconductor layer 310, and the upper electrode 350 may be formed on the other one of the contact regions 314 of the oxide semiconductor layer 310. The upper electrode 350 may be formed so as to surround an upper surface and side surface of the other one of the contact regions 314 of the oxide semiconductor layer 310.

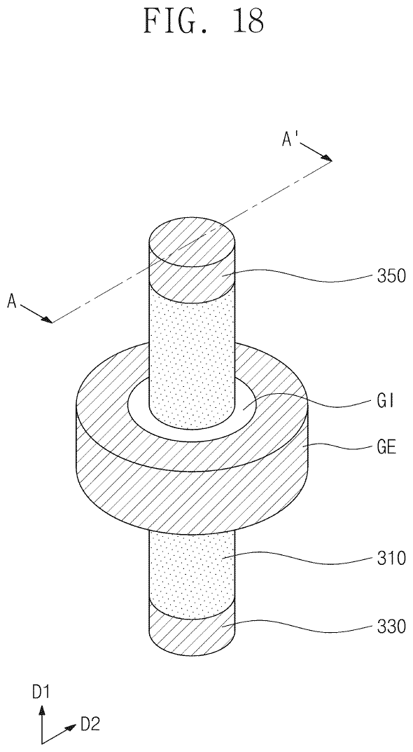

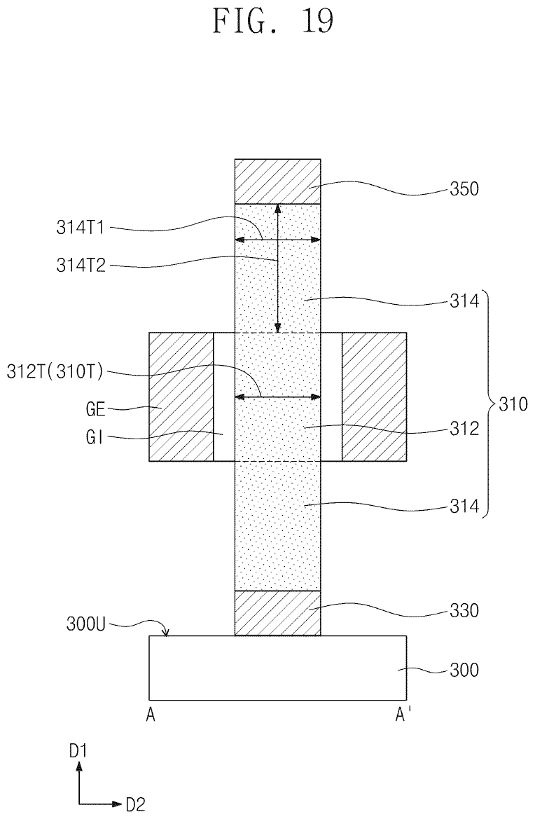

FIG. 18 is a perspective view schematically illustrating a semiconductor device according to some example embodiments of the inventive concepts, and FIG. 19 is a cross-sectional view taken along line A-A′ of FIG. 18. The semiconductor device of FIGS. 18 and 19 may be same as or similar in some respects to the semiconductor device of FIGS. 16 and 17, and therefore may be best understood with reference thereto where like numerals indicate like elements not described again in detail.

Referring to FIGS. 18 and 19, the thickness 310T of the oxide semiconductor layer 310 in the second direction D2 may be greater than 0 nm and equal to or less than 10 nm (or about 10 nm), for example, equal to or less than 3 nm (or about 3 nm). According to some example embodiments, the thickness 314T1 of each of the contact regions 314 of the oxide semiconductor layer 310 in the second direction D2 may be substantially the same as the thickness 312T of the channel region 312 of the oxide semiconductor layer 310 in the second direction D2. The thickness 314T2 of each of the contact regions 314 of the oxide semiconductor layer 310 in the first direction D1 may be greater than the thickness 312T of the channel region 312 of the oxide semiconductor layer 310 in the second direction D2.

The semiconductor device according to some example embodiments may be substantially the same as (or similar in some respects to) the semiconductor device described with reference to FIGS. 16 and 17 and may be formed using a method that is substantially the same as (or similar in some respects to) the method for manufacturing a semiconductor device described with reference to FIGS. 16 and 17.

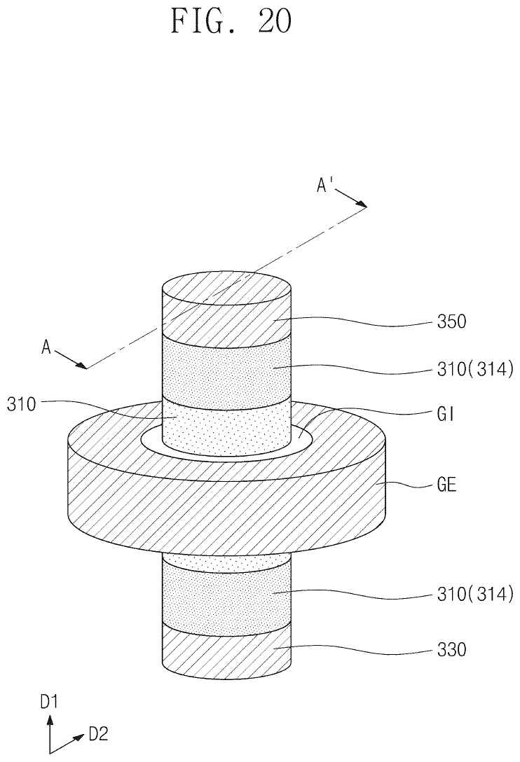

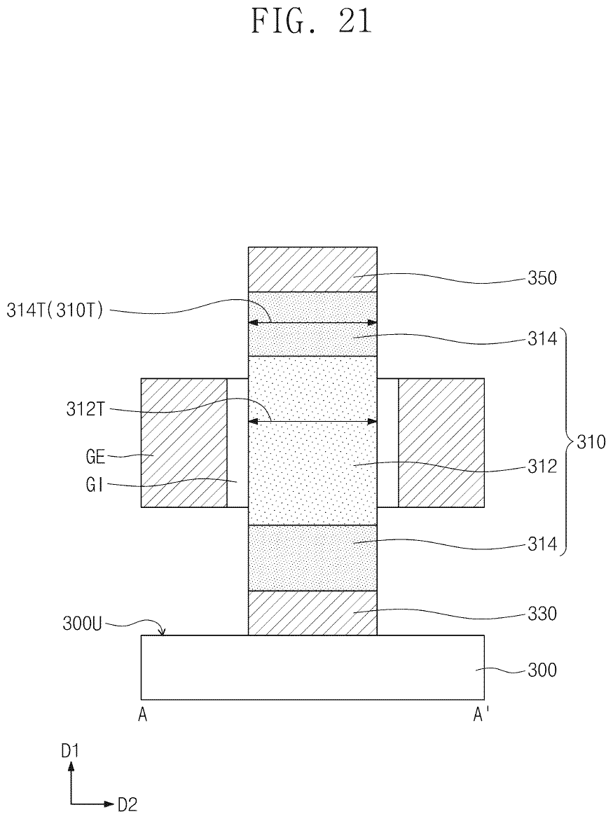

FIG. 20 is a perspective view schematically illustrating a semiconductor device according to some example embodiments of the inventive concepts, and FIG. 21 is a cross-sectional view taken along line A-A′ of FIG. 20. The semiconductor device of FIG. 20 may be same as or similar in some respects to the semiconductor device of FIGS. 16 and 17, and therefore may be best understood with reference thereto where like numerals indicate like elements not described again in detail.

Referring to FIGS. 20 and 21, the thickness 310T of the oxide semiconductor layer 310 in the second direction D2 may be greater than 0 nm and equal to or less than 10 nm (or about 10 nm), for example, equal to or less than 3 nm (or about 3 nm). According to some example embodiments, the thickness 314T of each of the contact regions 314 of the oxide semiconductor layer 310 in the second direction D2 may be substantially the same as the thickness 312T of the channel region 312 of the oxide semiconductor layer 310 in the second direction D2. The oxide semiconductor layer 310 may include a first metal. A content (or concentration) of the first metal in each of the contact regions 314 of the oxide semiconductor layer 310 may be higher than a content of the first metal in the channel region 312 of the oxide semiconductor layer 310. For example, the first metal may be indium (In), and an indium content in each of the contact regions 314 of the oxide semiconductor layer 310 may be higher than an indium content in the channel region 312 of the oxide semiconductor layer 310.

The semiconductor device according to some example embodiments is substantially the same as (or similar in some respects to) the semiconductor device described with reference to FIG. 13. In the semiconductor device of FIGS. 20 and 21, the oxide semiconductor layer 310, the gate electrode GE, the lower electrode 330, and the upper electrode 350 constitute a gate-all-around type transistor.

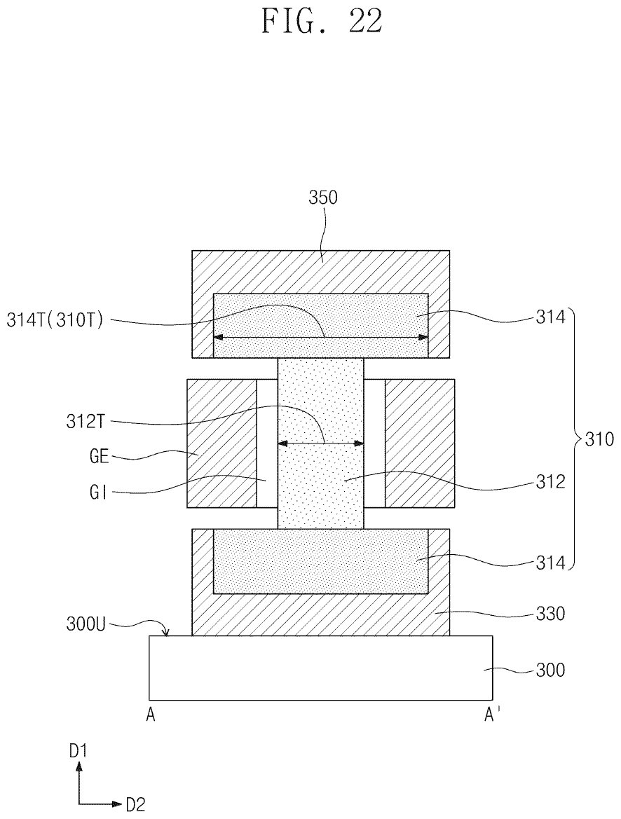

FIG. 22 is a cross-sectional view of a semiconductor device, taken along line A-A′ of FIG. 16, according to some example embodiments of the inventive concepts. The semiconductor device of FIG. 22 may be same as or similar in some respects to the semiconductor device of FIGS. 16 to 21, and therefore may be best understood with reference thereto where like numerals indicate like elements not described again in detail.

Referring to FIGS. 16 and 22, the thickness 310T of the oxide semiconductor layer 310 in the second direction D2 may be greater than 0 nm and equal to or less than 10 nm (or about 10 nm), for example, equal to or less than 3 nm (or about 3 nm). According to some example embodiments, the thickness 314T of each of the contact regions 314 of the oxide semiconductor layer 310 in the second direction D2 may be greater than the thickness 312T of the channel region 312 of the oxide semiconductor layer 310 in the second direction D2. In some example embodiments, the thickness 314T of each of the contact regions 314 may be equal to or less than 10 nm (or about 10 nm), for example, equal to or less than 3 nm (or about 3 nm). The oxide semiconductor layer 310 may include a first metal. A content (or concentration) of the first metal in each of the contact regions 314 of the oxide semiconductor layer 310 may be higher than a content of the first metal in the channel region 312 of the oxide semiconductor layer 310. For example, the first metal may be indium (In), and an indium content in each of the contact regions 314 of the oxide semiconductor layer 310 may be higher than an indium content in the channel region 312 of the oxide semiconductor layer 310.

The semiconductor device according to some example embodiments is substantially the same as (or similar in some respects to) the semiconductor device described with reference to FIG. 15. In the semiconductor device of FIG. 22, the oxide semiconductor layer 310, the gate electrode GE, the lower electrode 330, and the upper electrode 350 constitute a gate-all-around type transistor.

According to some example embodiments of the inventive concepts, contact regions of an oxide semiconductor layer may have an energy band gap Eg smaller than that of a channel region, and the charge neutrality level (CNL) of the oxide semiconductor layer may be higher than the conduction band minimum (CBM) Ec of the contact regions. Accordingly, resistance of the contact regions, electrically connected to electrodes, of the oxide semiconductor layer may decrease. In addition, the channel region of the oxide semiconductor layer may have a larger energy band gap Eg than that of the contact regions, and the CNL of the oxide semiconductor layer may be lower than the CBM Ec of the channel region. Accordingly, a threshold voltage Vth of the channel region of the oxide semiconductor layer may be greater than 0, and thus operational characteristics of a transistor including the oxide semiconductor layer may be improved. Furthermore, since the channel region of the oxide semiconductor layer has a larger energy band gap Eg than that of the contact regions, a leakage current of the transistor may be suppressed or reduced or limited. As a result, both electrical characteristics and operational characteristics of an oxide semiconductor channel transistor including the oxide semiconductor layer having a thickness of 10 nm (or about 10 nm) or less may be improved.

Example embodiments thus provide a semiconductor device including an oxide semiconductor channel transistor may have relatively higher integration and improved electrical characteristics and operational characteristics, and a method for manufacturing such a semiconductor device.

According to some example embodiments of the inventive concepts, a method for manufacturing a semiconductor device includes: forming an oxide semiconductor layer on a substrate, the oxide semiconductor layer including a channel region and contact regions spaced apart from each other in a first direction with the channel region therebetween; forming a gate electrode on the channel region of the oxide semiconductor layer; and forming electrodes respectively on the contact regions of the oxide semiconductor layer. According to some example embodiments, the forming of the oxide semiconductor layer may include adjusting at least one of a thickness, composition, crystallinity, or density of the oxide semiconductor layer such that an energy band gap of each of the contact regions is less than an energy band gap of the channel region.

According to some example embodiments, the oxide semiconductor layer may have a thickness in a second direction perpendicular to the first direction. According to some example embodiments, the forming of the oxide semiconductor layer may include adjusting the thickness of the oxide semiconductor layer such that a thickness of the channel region is less than a thickness of each of the contact regions.

According to some example embodiments, the oxide semiconductor layer may include a first metal. According to some example embodiments, the forming of the oxide semiconductor layer may include adjusting a composition of the oxide semiconductor layer such that a content of the first metal in each of the contact regions is higher than a content of the first metal in the channel region.

According to some example embodiments, the first metal may be indium (In).

According to some example embodiments, the forming of the oxide semiconductor layer may include adjusting a crystallinity of the oxide semiconductor layer such that the contact regions have a lower crystallinity than that of the channel region.

According to some example embodiments, the forming of the oxide semiconductor layer may include adjusting a density of the oxide semiconductor layer such that a density of oxide semiconductor in each of the contact regions is lower than a density of oxide semiconductor in the channel region.

According to some example embodiments, the forming of the oxide semiconductor layer may include adjusting at least one of the thickness, composition, crystallinity, or density of the oxide semiconductor layer such that a charge neutrality level (CNL) of the oxide semiconductor layer is higher than a conduction band minimum (CBM) of the contact regions and lower than a conduction band minimum (CBM) of the channel region.

According to some example embodiments, the oxide semiconductor layer may include an amorphous oxide semiconductor.

According to some example embodiments, a thickness of the oxide semiconductor layer in a second direction perpendicular to the first direction may be equal to or less than about 10 nm.

According to some example embodiments, the oxide semiconductor layer may include InGaZnO.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A semiconductor device comprising:
an oxide semiconductor layer on a substrate, the oxide semiconductor layer including a channel region and contact regions spaced apart from each other in a first direction with the channel region therebetween;
a gate electrode on the channel region of the oxide semiconductor layer; and
electrodes respectively on the contact regions of the oxide semiconductor layer,
wherein a thickness of the oxide semiconductor layer in a second direction perpendicular to the first direction is greater than 0 nm and equal to or less than 10 nm, and
an energy band gap of each of the contact regions of the oxide semiconductor layer is less than an energy band gap of the channel region of the oxide semiconductor layer.

2. The semiconductor device of claim 1, wherein a thickness of each of the contact regions of the oxide semiconductor layer is greater than a thickness of the channel region of the oxide semiconductor layer.

3. The semiconductor device of claim 1,
wherein the oxide semiconductor layer includes a first metal, and
a content of the first metal in each of the contact regions of the oxide semiconductor layer is higher than a content of the first metal in the channel region of the oxide semiconductor layer.

4. The semiconductor device of claim 1, wherein the contact regions of the oxide semiconductor layer have a lower crystallinity than that of the channel region of the oxide semiconductor layer.

5. The semiconductor device of claim 1, wherein a density of oxide semiconductor in each of the contact regions of the oxide semiconductor layer is lower than a density of oxide semiconductor in the channel region of the oxide semiconductor layer.

6. The semiconductor device of claim 1, wherein the oxide semiconductor layer includes an amorphous oxide semiconductor.

7. The semiconductor device of claim 1,
wherein the oxide semiconductor layer includes indium (In), and
an indium content in each of the contact regions of the oxide semiconductor layer is higher than an indium content in the channel region of the oxide semiconductor layer.

8. The semiconductor device of claim 7, wherein a thickness of each of the contact regions of the oxide semiconductor layer is greater than a thickness of the channel region of the oxide semiconductor layer.

9. The semiconductor device of claim 1, wherein the first direction is parallel to an upper surface of the substrate, and the second direction is perpendicular to the upper surface of the substrate.

10. The semiconductor device of claim 1, wherein the first direction is perpendicular to an upper surface of the substrate, and the second direction is parallel to the upper surface of the substrate.

11. A semiconductor device comprising:
an oxide semiconductor layer on a substrate, the oxide semiconductor layer including a channel region and contact regions spaced apart from each other in a first direction with the channel region therebetween;
a gate electrode on the channel region of the oxide semiconductor layer; and
electrodes respectively on the contact regions of the oxide semiconductor layer,
wherein the oxide semiconductor layer includes an amorphous oxide semiconductor, and
an energy band gap of each of the contact regions of the oxide semiconductor layer is less than an energy band gap of the channel region of the oxide semiconductor layer.

12. The semiconductor device of claim 11,
wherein the oxide semiconductor layer has a thickness in a second direction perpendicular to the first direction, and
a thickness of each of the contact regions of the oxide semiconductor layer is greater than a thickness of the channel region of the oxide semiconductor layer.

13. The semiconductor device of claim 11,
wherein the oxide semiconductor layer includes a first metal, and
a content of the first metal in each of the contact regions of the oxide semiconductor layer is higher than a content of the first metal in the channel region of the oxide semiconductor layer.

14. The semiconductor device of claim 13, wherein the first metal is indium (In).

15. A semiconductor device comprising:
an oxide semiconductor layer on a substrate, the oxide semiconductor layer including a channel region and contact regions spaced apart from each other in a first direction with the channel region therebetween;
a gate electrode on the channel region of the oxide semiconductor layer; and
electrodes respectively on the contact regions of the oxide semiconductor layer,
wherein the oxide semiconductor layer is configured such that a charge neutrality level (CNL) of the oxide semiconductor layer is higher than a conduction band minimum (CBM) of the contact regions of the oxide semiconductor layer and lower than a conduction band minimum (CBM) of the channel region of the oxide semiconductor layer.

16. The semiconductor device of claim 15,
wherein the oxide semiconductor layer has a thickness in a second direction perpendicular to the first direction, and
a thickness of each of the contact regions of the oxide semiconductor layer is greater than a thickness of the channel region of the oxide semiconductor layer.

17. The semiconductor device of claim 15,
wherein the oxide semiconductor layer includes indium (In), and
an indium content in each of the contact regions of the oxide semiconductor layer is higher than an indium content in the channel region of the oxide semiconductor layer.

18. The semiconductor device of claim 15, wherein the contact regions of the oxide semiconductor layer have a lower crystallinity than that of the channel region of the oxide semiconductor layer.

19. The semiconductor device of claim 15, wherein a density of oxide semiconductor in each of the contact regions of the oxide semiconductor layer is lower than a density of oxide semiconductor in the channel region of the oxide semiconductor layer.

20. The semiconductor device of claim 15, wherein the oxide semiconductor layer includes an amorphous oxide semiconductor.
